(19) United States
(12) Patent Application Publication
(10) Pub. No.: US 2009/0004385 A1
(43) Pub. Date: Jan. 1, 2009

(54) Copper precursors for deposition processes

(76) Inventors: James M. Blackwell, Portland, OR (US); Darryl J. Morrison, Calgary (CA); Adrien R. Lavoie, Beaverton, OR (US)

Correspondence Address: CAVEN & AGHEVLI;c/o INTELLEVATE, LLC, P.O. BOX 52050, MINNEAPOLIS, MN, 55402, US

(21) Appl. No.: 11/824,291

(22) Filed: Jun. 29, 2007

(51) Int. Cl. C23C 16/00

(52) U.S. Cl. 427/250

(57) ABSTRACT

In one embodiment, a method comprises providing a chemical phase deposition copper precursor within a chemical phase deposition chamber; and depositing a metal film onto a substrate with the copper precursor by a chemical phase deposition process.

### BACKGROUND

The subject matter described herein relates generally to semiconductor processing, and more particularly to copper precursors for deposition processes.

The microelectronic device industry continues to scale down the dimensions of the structures within integrated circuits. Present semiconductor technology now permits single-chip microprocessors with many millions of transistors, operating at speeds of tens or even hundreds of millions of instructions per second. These transistors are generally connected to one another or to devices external to the microelectronic device by conductive traces and contacts through which electronic signals are sent or received. One process used to form contacts is known as a “damascene process.” In a typical damascene process, a photoresist material is patterned on a dielectric material and the dielectric material is etched through the photoresist material patterning to form an opening for a via or an interconnect line. The photoresist material is then removed (e.g., by an oxygen plasma) and a thin film such as an adhesion layer, a barrier layer, or a seed layer are deposited within the opening. The opening is then filled, e.g., by deposition, with the conductive material (e.g, such as metal and metal alloys thereof). A thin film such as an adhesion layer, barrier layer, or seed layer is deposited within the recessed area and may be formed by a physical vapor deposition (PVD) process (sputtering). But, as the widths of the openings in the dielectric layer are scaled down below 50 nm and as aspect ratios of the openings increase, it becomes difficult to conformally deposit the thin films by by sputtering. The ability to cover the sidewalls with the thin film using PVD in narrow openings is diminished and there may be excess overhang of the film. Similar problems result from sputtering the thin films within the openings. Additionally, it becomes difficult to deposit thin films having a thickness of less than 50 angstroms by PVD. The thicker films that result from PVD take up a greater percentage of the space within the openings and thus increase line resistance and RC delay.

### BRIEF DESCRIPTION OF THE DRAWINGS

The disclosed embodiments will be better understood from a reading of the following detailed description, taken in conjunction with the accompanying drawings in which:

FIG. 1 is a schematic illustration of a method to form copper precursors, according to embodiments.

FIG. 2 is a schematic illustration of copper precursors, according to embodiments.

FIGS. 3A and 3B are schematic illustrations of the molecular structure of a component used in forming copper precursors.

FIG. 4 is a schematic illustration of a method to form copper precursors, according to embodiments.

FIG. 5 is a schematic illustration of copper precursors, according to embodiments.

FIG. 6 is a schematic illustration of the thermal decomposition of copper precursors, according to embodiments.

FIG. 7 is a flowchart illustrating a semiconductor processing method, according to embodiments.

FIGS. 8A-8G are schematic illustrations of a semiconductor device, according to embodiments.

### DETAILED DESCRIPTION

Described herein are methods of chemical phase deposition utilizing copper precursors. In the following description numerous specific details are set forth. One of ordinary skill in the art, however, will appreciate that these specific details are not necessary to practice embodiments of the invention. While certain embodiments of the invention are described and shown in the accompanying drawings, it is to be understood that such embodiments are merely illustrative and not restrictive of the current invention, and that this invention is not restricted to the specific constructions and arrangements shown and described because modifications may occur to those ordinarily skilled in the art. In other instances, well known semiconductor fabrication processes, techniques, materials, equipment, etc., have not been set forth in particular detail in order to not unnecessarily obscure embodiments of the present invention.

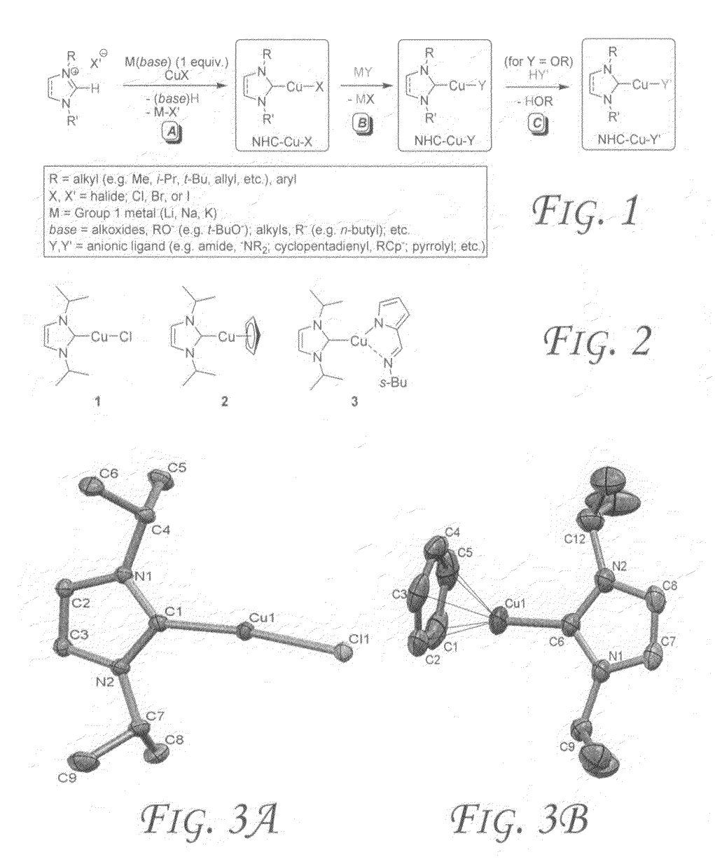

FIG. 1 is a schematic illustration of a method to form copper precursors, according to embodiments. Deprotonation N,N′-dialkyl- or N,N′-diarylimidazolium salts with an appropriate base (e.g. NaO-t-Bu) in the presence of copper(I) halides (e.g. CuCl) leads to the N-heterocyclic carbene copper(I) halide, NHC—Cu—X, as illustrated in FIG. 1 by reference (A). Treatment of the copper(I) halides NHC—Cu—X with appropriate metal salts of organic ligands (e.g., sodium cyclopentadienylide, NaC5H5 or NaCp; lithium amides, LiNR2; or sodium tert-butoxide, NaOtBu) results in new copper(I) compounds NHC—Cu—Y, as illustrated in FIG. 1 by reference (B). In the case of N-heterocyclic carbene copper(I) alkoxides, NHC—Cu—OR, treatment with organic compounds HY′ with sufficient acidity (e.g., pyrroles, phenols, cyclopentadienes, etc.) leads directly to new derivatives NHC—Cu—Y′ with the formation of volatile alcohol by-products HOR, as illustrated in FIG. 1 by reference (C).

FIG. 2 is a schematic illustration of copper precursors, according to embodiments, and FIGS. 3A and 3B are schematic illustrations of the molecular structure of a component used in forming copper precursors. Methods A-C (in FIG. 1) were verified with the synthesis of three examples, identified in FIG. 2 with reference numerals 1, 2, and 3, from N,N′-diisopropylimidazolium chloride. N,N′-Diisopropylimidazolidene (DIPI) copper(I) chloride (DIPICuCl, 1) is a colorless crystalline solid that sublimes at 100° C./20 mTorr. Compound 1 in FIG. 2 is monomeric in solution (NMR) and the solid state (X-Ray, FIG. 3A). Treatment of compound 1 with NaCp in a THF solution leads to the monomeric (FIG. 3B) cyclopentadienyl derivative DIPICuCp, 2, which is thermally robust at its sublimation temperature 90° C./20 mTorr. The 2-(N-sec-butylimino)pyrrolyl derivative 3 was prepared via treatment of DIPICuOtBu with the appropriate substituted pyrrole. Pyrrolyl derivative 3 is also thermally stable and sublimes at 110° C./20 mTorr. Table 1 provides key physical data for tested compounds

TABLE 1

| | | Sublimation | |
|---|---|---|---|
| | Molecular | Temp. | |
| | Weight | at 20 mTorr | |
| Compound | (g/mol) | (° C.) | Comments |
| 1 | 251 | 100 | Colorless crystalline compound; |
| | | | monomeric in the solid state; |
| | | | volatile source of CuCl |
| 2 | 296 | 90 | Colorless crystalline compound; |
| | | | all C, H, N source of Cu |
| 3 | 365 | 110 | Yellow solid; all C, H, N source |
| | | | of Cu |

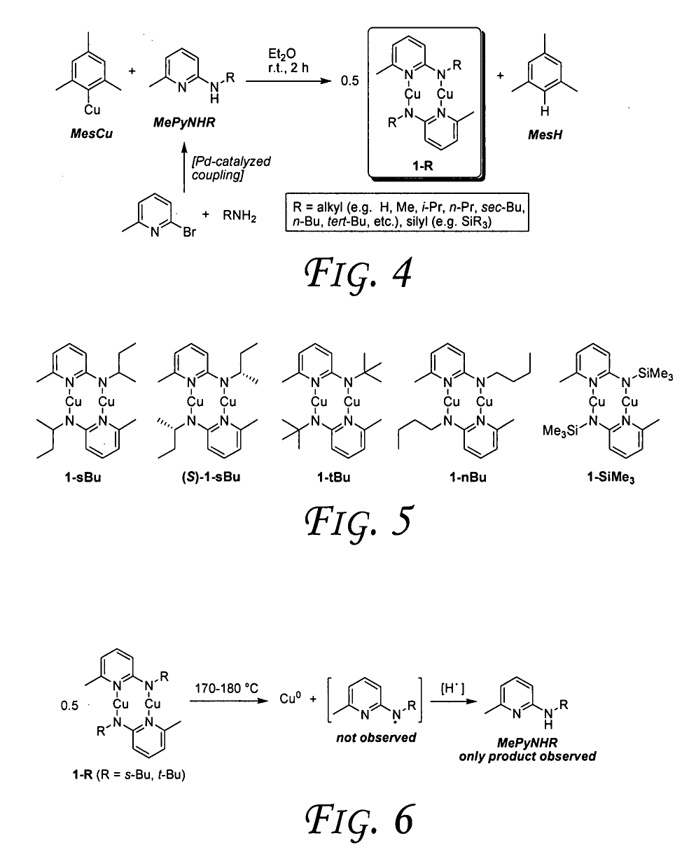

FIG. 4 is a schematic illustration of a method to form copper precursors, according to embodiments, and FIG. 5 is a schematic illustration of copper precursors, according to embodiments. In some embodiments, dimeric, volatile aminopyridinate copper(I) compounds 1-R may be prepared and their physical properties and thermal decomposition were investigated. Varying the chemical structure of the nitrogen-bonded alkyl/silyl group (N-alkyl, N—R; or N-silyl, N—SiR3) allows for tuning of the melting points and volatilities of the resulting compounds 1-R. A volatile, low-melting precursor 1-sBu may be used as a stable and deliverable precursor for CVD of conductive Cu films on PVD Ru or Ta seed substrates.

In some embodiments, aminopyridinate copper(I) compounds 1-R may prepared by the reaction of 2-N-alkylamino- or 2-N-silylamino-6-methylpyridines (MePyNHR) with mesitylcopper(I) (MesCu) in diethyl ether solvent at room temperature. FIGS. 2 and 3. The 2-alkylamino-6-methylpyridines were prepared by Pd-catalyzed coupling of the appropriate primary amines (RNH2) with 2-bromo-6-methylpyridine; FIG. 2. Yields of 1-R were essentially quantitative with the only by-product being mesitylene (1,3,5-trimethylbenzene; MesH), which is volatile and easily removed under vacuum. Data from variable temperature solution 1H NMR spectroscopy, single crystal X-ray diffraction (1-nBu), and comparison of the properties of 1-R with the known compound 1-SiMe3 were all consistent with dimeric structures for 1-R in solution and solid-states.

Table 2 presents physical data for the four compounds presented in FIG. 5. Referring to FIG. 4, the N-sec-butyl derivatives 1-sBu and its enantiomerically pure analog (S)-1-sBu are the most volatile, subliming at 90° C./20 mTorr. However, the racemic version 1-sBu (m.p. 45-50° C.), which exists as a mixture of diastereomers, has a lower melting point than (S)-1-sBu (m.p. 85-90° C.). Compounds 1-tBu and 1-SiMe3 are thermally stable and solid at their sublimation temperatures (both ˜120° C./20 mTorr).

TABLE 2

| | Molecular | | Sublimation |
|---|---|---|---|
| | Weight | Melting Point | Temp. at 20 mTorr |
| Compound | (g/mol) | (° C.) | (° C.) |
| 1-sBu | 452 | 50 | 90 |
| (S)-1-sBu | 452 | 85-90 | 90 |
| 1-tBu | 452 | ~170 (dec.) | 120 |
| 1-nBu | 452 | n.d. | n.d. |
| 1-SiMe₃ | 486 | >120 | 120 |

Compound 1-sBu may be used as a precursor for the CVD of conductive copper films on Ru seed layers. Table 3 presents data on the selective CVD of conductive copper films with the precursor [(MePyNsBu)Cu]2, 1-sBu. Film growth was observed on 50 Å PVD Ru seed layers with source temperatures of 100-110° C. substrate temperatures ranging from 850-400° C. No film growth was observed on the surrounding oxide. Neither forming gas (5% H2/N2) nor NH3 co-reactants affected film growth.

TABLE 3

| | Source | Substrate^{a} | Number | | R_{S} of Ru | R_{S} |
|---|---|---|---|---|---|---|
| | Temp. | Temp. | of | Co- | Seed Layer | After Run |
| Entry | (° C.) | (° C.) | Cycles | reactant | (Ω/sq.) | (Ω/sq.)^{c} |
| 1 | 100 | 450 | 400 | none | 540 | 388 |
| 2 | 110 | 450 | 400 | none | 621 | 290 |
| 3 | 110 | 350 | 400 | none | 589 | 172 |
| 4 | 110 | 850 | 400 | none | 533 | 199 |
| 5 | 110 | 800 | 400 | none | 537 | 436 |
| 6 | 110 | 300 | 400 | FG | 634 | 187 |
| 7 | 110 | 350 | 400 | FG | 603 | 157 |
| 8 | 110 | 400 | 400 | FG | 620 | 172 |
| 9 | 110 | 350 | 800 | FG | 780 | 175 |
| 10 | 110 | 350 | 400 | NH₃ | 736 | 153 |

In separate experiments, samples of 1-sBu and 1-tBu were decomposed at 170-180° C. under an inert atmosphere of N2 and the products were analyzed using 1H NMR spectroscopy and gas chromatography/mass spectrometry (GC/MS). FIG. 6 is a schematic illustration of the thermal decomposition of copper precursors, according to embodiments. The only observable products were Cu metal and their respective 2-(N-butylamino)-6-pyridine components. These products are consistent with a mechanism involving homolytic cleavage of Cu—N amide bonds with subsequent quenching of the nitrogen radical by a source of H (e.g., the glass walls of the flask). There was no evidence of products expected from other decomposition mechanisms known to be operable for copper(I) compounds (e.g. disproportionation, β-hydride elimination).

In some embodiments, the compounds described herein may be used as precursors for chemical vapor deposition (CVD) and/or atomic layer deposition (ALD), or hybrid CVD/ALD processes of metallic copper seed. The precursors in these methods may be liquid, solid or gaseous precursors delivered within a solution or carried by an inert gas or directly fed at any concentration to the surface on which the film is to be deposited.

In some embodiments, a thin metal film is formed by chemical vapor deposition (CVD) by the decomposition and/or surface reactions of the metal precursor. The gaseous compounds of the materials to be deposited are transported to a substrate surface where a thermal reaction/deposition occurs. Reaction byproducts are then exhausted out of the system. In an embodiment of the current invention, the copper precursor or precursors are introduced into a CVD reaction chamber. A thin metal film is then formed on the substrate in a deposition process. The growth of the thin metal film may stop by the consumption of the copper precursor present within the chamber or by purging the chamber of the gases. By this method the thickness of the thin metal film may be controlled.

Atomic layer deposition (ALD) grows a film layer by layer by exposing a substrate to alternating pulses of the copper precursor or precursors and the co-reactant, where each pulse may include a self-limiting reaction and results in a controlled deposition of a film. Pulse and purge duration lengths are arbitrary and depend on the intended film properties. Atomic layer deposition is valuable because it forms the thin metal film to a specified thickness and may conformally coat the topography of the substrate on which it forms the thin metal film.

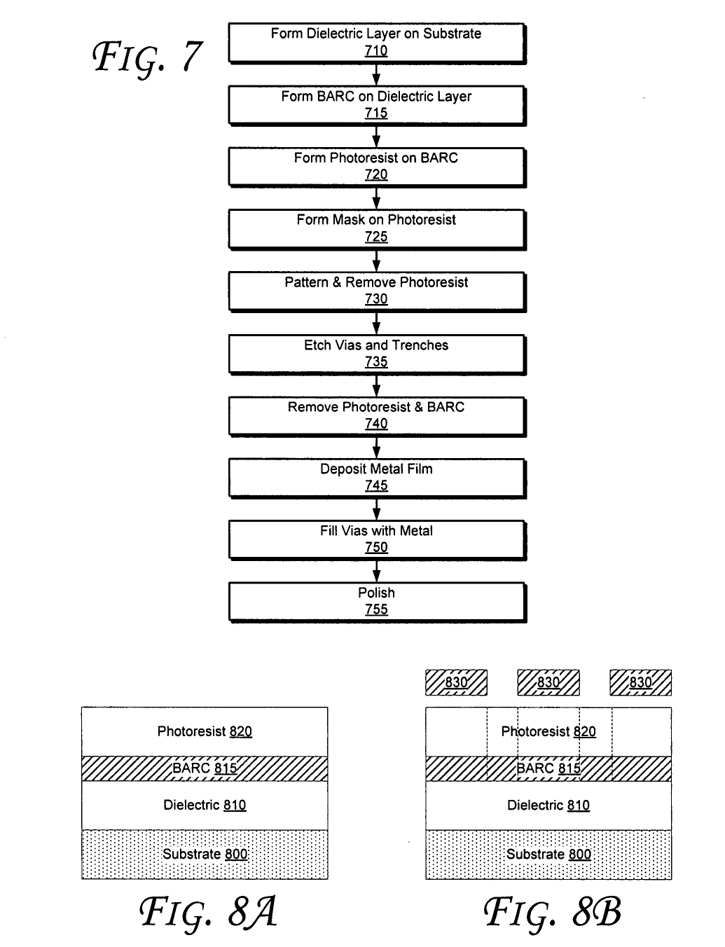

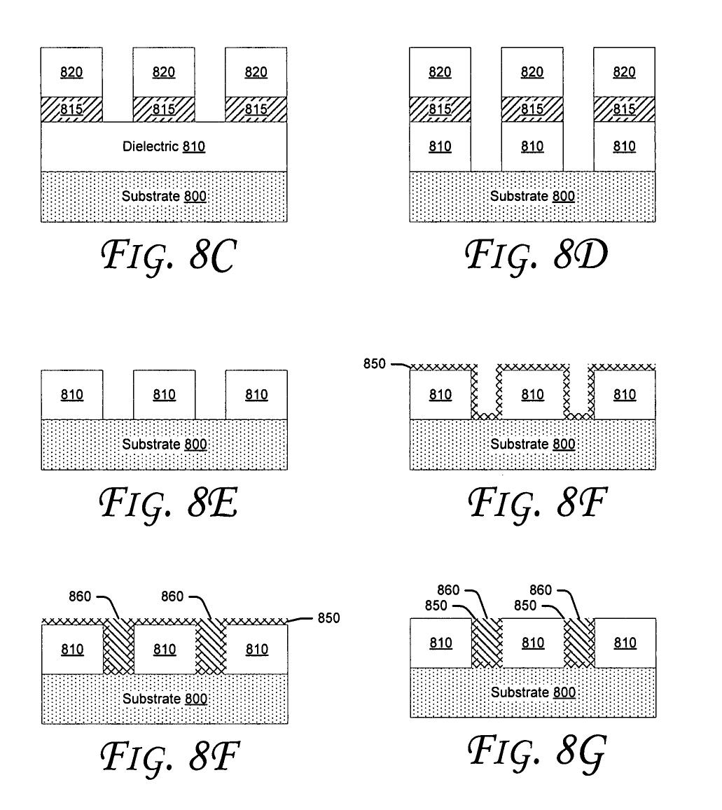

In an embodiment, the thin films formed by a chemical phase deposition process utilizing copper precursors may be deposited within openings in a dielectric layer to form a barrier layer, a seed layer, or an adhesion layer for vias or interconnect lines in an integrated circuit. FIG. 7 is a flowchart illustrating a semiconductor processing method, according to embodiments, and FIGS. 8A-8G are schematic illustrations of a semiconductor device, according to embodiments.

Referring first to FIG. 8a, substrate 800 is provided. Substrate 800 may be any surface generated when making an integrated circuit upon which a conductive layer may be formed. In this particular embodiment the substrate 800 may be a semiconductor such as silicon, germanium, gallium arsenide, silicon-on-insulator or silicon on sapphire. Referring to FIG. 7, at operations 710 a dielectric layer 810 is formed on top of substrate 800. Dielectric layer 810 may be an inorganic material such as silicon dioxide or carbon doped oxide (CDO) or a polymeric low dielectric constant material such as poly(norbornene) such as those sold under the tradename UNITY.™., distributed by Promerus, LLC; polyarylene-based dielectrics such as those sold under the tradenames “SiLK.™.” and “GX-3.™.”, distributed by Dow chemical Corporation and Honeywell Corporation, respectively; and poly(aryl ether)-based materials such as that sold under the tradename “FLARE.™.”, distributed by Honeywell Corporation. The dielectric layer 810 may have a thickness in the approximate range of 2,000 and 20,000 angstroms.

At operation 715, a bottom anti-reflective coating (BARC) 815 may be formed over the dielectric layer 810. In embodiments where non-light lithography radiation is used a BARC 815 may not be necessary. The BARC 815 is formed from an anti-reflective material that includes a radiation absorbing additive, typically in the form of a dye. The BARC 815 may serve to minimize or eliminate any coherent light from re-entering the photoresist 820, which is formed over the BARC 815 during irradiation and patterning of the photoresist 820. The BARC 815 may be formed of a base material and an absorbant dye or pigment. In one embodiment, the base material may be an organic material, such as a polymer, capable of being patterned by etching or by irradiation and developing, like a photoresist. In another embodiment, the BARC 815 base material may be an inorganic material such as silicon dioxide, silicon nitride, and silicon oxynitride. The dye may be an organic or inorganic dye that absorbs light that is used during the exposure step of the photolithographic process.

At operation 720 a photoresist 820 is formed over the BARC 815. The photoresist 820, in this particular embodiment, is a positive resist. In a positive tone photoresist the area exposed to the radiation will define the area where the photoresist will be removed. At operation 725, a mask 830 is formed over the photoresist 820 (FIG. 8B). At operation 730, the photoresist 820 and the BARC 815 are patterned by exposing the masked layer to radiation. A developer solution is then applied to the photoresist and the irradiated regions 825 of the photoresist 820 that were irradiated may be solvated by the solution (FIG. 8C).

At operation 735, vias or trenches 840 are etched through dielectric layer 810 down to substrate 800, as illustrated in FIG. 8D. Conventional process steps for etching through a dielectric layer 810 may be used to etch the via, e.g., a conventional anisotropic dry etch process. When silicon dioxide is used to form dielectric layer 810, the vias or trenches 840 may be etched using a medium density magnetically enhanced reactive ion etching system (“MERIE” system) using fluorocarbon chemistry. When a polymer is used to form dielectric layer 810, a forming gas chemistry, e.g., one including nitrogen and either hydrogen or oxygen, may be used to etch the polymer. The aspect ratios of the height to the width of the vias or trenches 840 may be in the approximate range of 1:1 and 20:1. The openings of the vias or trenches 840 may be less than approximately 1000 nm (nanometers) wide or more particularly less than approximately 50 nm wide.

At operation 740, the photoresist 820 and the BARC 815 are removed. Photoresist 820 and BARC 815 may be removed using a conventional etching procedure as illustrated in FIG. 8E.

At operation 745, a thin metal film 850 is then conformally formed over the vias or trenches 240 and the dielectric 810 as illustrated in FIG. 8F, e.g., by a chemical phase deposition process utilizing a copper precursor as described above. As described above, the copper precursor may be utilized in a chemical vapor deposition (CVD) process or an atomic layer deposition (ALD) process. These processes may form thin conformal films and films that are amorphous or polycrystalline. This thin stack composed of multiple metal films 850 may serve as a barrier layer, a seed layer, an adhesion layer, or a combination of any of these types of films. The thin stack of metal films 850 may have a thickness in the approximate range of 5 Angstrom to Angstroms or more particularly a thickness of less than 50 Angstrom. The purpose of a barrier layer is to prevent metals such as copper from diffusing out of the vias or trenches and and causing shorts. The formation of an amorphous or microcrystalline film is valuable in forming a barrier layer, and embodiments of the current invention cover the formation of polycrystalline or amorphous metals. A seed layer has catalyzing properties and provides a seed for the deposition of the bulk metal within the vias or trenches 240 by electroplating or electroless plating. In an embodiment, the barrier layer may also serve as the seed layer. An adhesion layer may improve the adhesion of the thin metal film 850 to the dielectric layer 810 or to another metal. The deposition of a stack of thin metal films 850 that has the properties of a barrier layer, a seed layer, or an adhesion layer may be formed by performing a chemical phase deposition process with a copper precursor that includes a metal or metals having those properties. The stack of thin metal films 850 may also be formed as an alloy or composite having any combination of these properties or as an alloy of different metallic elements having the same properties.

Post-deposition processes may be used tailor the properties of the thin metal film 850. For example, a post deposition process may be used to segregate the metals within an alloyed thin metal film 850, to form a concentration gradient of the metals within the alloyed thin metal film 850, to stuff grain boundaries of the film with carbon, or to incorporate a light element such as carbon or nitrogen. An energy induced process, such as a thermal anneal, may be used to segregate the metals within the film or to form a concentration gradient of the metals within the film due to the different solubilities of the different metals within the alloy or due to the precipitation of a metal. An energy induced anneal in combination with a surface reactive gas may be used to incorporate light elements such as carbon or nitrogen into the film by diffusion. A differential laser anneal may be used to heat small areas of the film to cause grain growth, precipitation, or segregation of a particular area of the film. Selective etching or ion milling may be used to thin the top layer of metal or to thin specific portions of the thin metal film 850.

At operation 750 a metal layer 860 is then deposited into the vias or trenches 840 (FIG. 8F). The metal layer may be copper, copper alloy (alloy metals include but are not limited to Al, Au, Ag, Sn, Mg), gold, ruthenium, cobalt, tungsten, or silver. In one particular embodiment copper is deposited to form the metal layer 860. Copper may be deposited by electroplating or electroless (catalytic) deposition that require first depositing a seed material in the vias or trenches 840.

At operation 755 the surface is polished, e.g., by a CMP process. FIG. 8G illustrates the structure that results after filling vias or trenches 840 with a conductive material. Although the embodiment illustrated in FIG. 8F illustrates only one dielectric layer 810 and vias or trenches 840, the process described above may be repeated to form additional conductive and insulating layers until the integrated circuit is produced.

Once the integrated circuit is complete the wafer on which the interconnect layers has been formed is cut into dice. Each die is then packaged individually. In one exemplary embodiment the die has copper bumps that are aligned with the package solder bumps on the pads of the package substrate and coupled to one another by heat. Once cooled, the package solder bumps become attached to the die solder bumps. The gap between the die and the package substrate may be filled with an underfill material. A thermal interface material and a heat sink may then formed over the die to complete the package.

In the description and claims, the terms coupled and connected, along with their derivatives, may be used. In particular embodiments, connected may be used to indicate that two or more elements are in direct physical or electrical contact with each other. Coupled may mean that two or more elements are in direct physical or electrical contact. However, coupled may also mean that two or more elements may not be in direct contact with each other, but yet may still cooperate or interact with each other.

Reference in the specification to “one embodiment” “some embodiments” or “an embodiment” means that a particular feature, structure, or characteristic described in connection with the embodiment is included in at least an implementation. The appearances of the phrase “in one embodiment” in various places in the specification may or may not be all referring to the same embodiment.

Although embodiments have been described in language specific to structural features and/or methodological acts, it is to be understood that claimed subject matter may not be limited to the specific features or acts described. Rather, the specific features and acts are disclosed as sample forms of implementing the claimed subject matter.

What is claimed is:

1. A method, comprising:
providing a chemical phase deposition copper precursor within a chemical phase deposition chamber; and
depositing a metal film onto a substrate with the copper precursor by a chemical phase deposition process.

2. The method of claim 1, wherein the chemical phase deposition process is selected from the group consisting of chemical vapor deposition, atomic layer deposition, hybrid CVD/ALD.

3. The method of claim 1, wherein the copper precursor comprises a N-heterocyclic carbene (NHC) copper(I) compound having a formula NHC—Cu—X, wherein X represents a halide atom) or NHC—Cu—Y (Y=anionic organic ligand)

4. The method of claim 1, wherein the copper precursor comprises a N-heterocyclic carbene (NHC) copper(I) compound having a formula NHC—Cu—Y, wherein Y represents a an anionic organic ligand.

5. The method of claim 1, wherein the copper precursor comprises aminopyridinate copper compounds.

6. The method of claim 1, wherein the copper precursor comprises at least one coreactant comprising hydrogen, forming gas, and hydrogen plasma.

7. A method, comprising:
providing a chemical phase deposition copper precursor within a chemical phase deposition chamber; and
depositing a metal film onto a substrate with the copper precursor by a chemical vapor deposition process.

8. The method of claim 7, wherein the chemical vapor deposition process comprises a thermal deposition process.

9. The method of claim 7, wherein the copper precursor comprises a N-heterocyclic carbene (NHC) copper(I) compound having a formula NHC—Cu—X, wherein X represents a halide atom) or NHC—Cu—Y (Y=anionic organic ligand)

10. The method of claim 7, wherein the copper precursor comprises a N-heterocyclic carbene (NHC) copper(I) compound having a formula NHC—Cu—Y, wherein Y represents a an anionic organic ligand.

11. The method of claim 7, wherein the copper precursor comprises aminopyridinate copper compounds.

12. The method of claim 7, wherein the copper precursor comprises at least one coreactant comprising hydrogen, forming gas, and hydrogen plasma.
